(19) United States
(12) Patent Application Publication
(10) Pub. No.: US 2005/0275096 A1
(43) Pub. Date: Dec. 15, 2005

(54) Pre-doped reflow interconnections for copper pads

(76) Inventors: Kejun Zeng, Coppell, TX (US); Tz-Cheng Chiu, Plano, TX (US); Rebecca L. Holdford, Garland, TX (US)

Correspondence Address: TEXAS INSTRUMENTS INCORPORATED, P O BOX 655474, M/S 3999, DALLAS, TX, 75265, US

(21) Appl. No.: 10/919,144

(22) Filed: Aug. 16, 2004

Related U.S. Application Data
(60) Provisional application No. 60/578,991, filed on Jun. 11, 2004.

(51) Int. Cl. H01L 23/52

(52) U.S. Cl. 257/737; 257/738; 257/762; 257/772; 257/780; 257/784

(57) ABSTRACT

A metal interconnect structure (100) comprising a bond pad (110) of copper; a body (103) of eutectic alloy in contact with the bond pad, this alloy including copper; and a contact pad (120) comprising copper in contact with the alloy body. When the eutectic alloy is tin/lead, the alloy includes copper in an amount greater than 0.08 weight percent and less than 2.0 weight percent. When the eutectic alloy is tin/silver, the alloy includes copper in an amount greater than 0.9 weight percent and less than 2.0 weight percent.

### FIELD OF THE INVENTION

The present invention is related in general to the field of semiconductor devices and more specifically to a method of controlling metal interdiffusion and diminishing Kirkendall voids in interconnections, especially in solder joints, to improve device reliability.

### DESCRIPTION OF THE RELATED ART

When integrated circuits on semiconductor chips are to be interconnected to external circuitry on a substrate using reflow materials such as solder, the parts to be assembled have to undergo at least one temperature rise to above the melting temperature of the reflow material, followed by a cooling cycle. After completing this process, the finished assembly often has to be subjected to annealing steps, consisting typically of repeated temperature swings for an extended period of time. Finally, the assembled parts frequently have to be tested to determine their reliable functioning after repeated exposure to failure-accelerating conditions such as extreme temperature excursions and/or elevated humidity.

The failure mechanisms studied since the early development of reflow-assembled parts in the late 1960s (spearheaded by IBM) predominantly were stress-induced joint fatigue, creep and cracking. Similarly, stress-initiated failures have been at the center of research attention for complete device packages assembled on external parts using reflow materials such as solder. Over the years, relatively little attention has been directed towards the progressive changes in the assembly joints caused by intermetallic effects such as metal interdiffusions, compound formation, and lattice mismatches. These changes are particularly pronounced for certain metals, as recent experimental results have clearly shown; the changes are caused by metal interdiffusions and lead to irreversible intermetallic changes. The changes may contribute significantly to diminished reliability of reflow-assembled parts.

Since the introduction of copper as interconnecting metallization in integrated circuits, copper pads in direct contact with solder have been found to exhibit weaknesses affecting the reliability of solder joints. The favorite solution has been the implementation of a nickel layer as a diffusion barrier between copper and solder to limit the solder reaction. The electroless process, however, commonly used for depositing the nickel introduced a problem of its own, the black pad caused by the galvanic corrosion of the electroless nickel plating during the immersion gold plating. Copper surface finishes proposed so far as alternatives are ending up in direct copper/solder contacts: An organic surface protection film will evaporate at the high temperature needed for solder reflow; a thin layer of gold will be dissolved into the molten solder; a thin layer of tin will also be dissolved into the molten solder; similarly, an original thin solder film will be dissolved.

### SUMMARY OF THE INVENTION

A need has arisen for a straightforward solution to improve the reliability of direct copper/solder contacts. A careful investigation has been conducted to study the interface between copper and solder under the long term influence of elevated temperatures or repeated temperature cycles, commonly referred to as “aging”. This investigation has confirmed that after aging a large amount of Kirkendall voids has formed at the interface between solder and copper, which greatly decreases the interfacial strength of the intermetallic joint.

The Kirkendall voids as a symptom of stress and crystal lattice mismatch are the result of fast diffusion of copper through the interface to the solder side. This explanation makes it obvious that under the conditions of repeated temperature cycles, high temperature storage (i.e., at temperatures>100° C.), and device working temperatures of >100° C., none of the above listed contact pad surface materials will reliably work. Rather, the solution to eliminate Kirkendall voids has to come from kinetically slowing down the diffusion rate of copper through the interface. This can be realized by adding copper into the solder. The amount of copper to be added depends on the composition of the solder alloy.

One embodiment of the present invention is a metal interconnect structure comprising a bond pad of copper; a body of eutectic tin/lead alloy in contact with the bond pad, this alloy including copper in an amount greater than 0.08 weight percent and less than 2.0 weight percent; and a contact pad comprising copper in contact with the alloy body.

Another embodiment of the present invention is a metal interconnect structure comprising a bond pad of copper; a body of eutectic tin/silver alloy in contact with the bond pad, this alloy including copper in an amount greater than 0.9 weight percent and less than 2.0 weight percent; and a contact pad comprising copper in contact with the alloy body.

Another embodiment of the present invention is a metal interconnect structure comprising a bond pad of a first metal and a body of reflow alloy in contact with the bond pad. The alloy includes a quantity of the first metal sufficient to reduce the diffusion rate of the first metal into the alloy, and to substantially prevent the formation of Kirkendall voids at the first metal/alloy body intermetallic joint, and concurrently to keep the alloy melting temperature less than about 20° C. above the eutectic temperature of the alloy. Finally, the structure has a contact pad comprising a third metal in contact with the alloy body.

The technical advances represented by certain embodiments of the invention will become apparent from the following description of the preferred embodiments of the invention, when considered in conjunction with the accompanying drawings and the novel features set forth in the appended claims.

### BRIEF DESCRIPTION OF THE DRAWINGS

FIG. 1 illustrates a schematic cross section of a solder connection between a semiconductor device portion and a substrate portion. The portion marked “A” is magnified in FIG. 2.

FIG. 2 is a magnified schematic view of the portion marked “A” in FIG. 1.

### DETAILED DESCRIPTION OF THE PREFERRED EMBODIMENTS

The present invention is related to U.S. patent application Ser. No. 10/434,316, filed on May 7, 2003 (Zeng, “Controlling Interdiffusion Rates in Metal Interconnection Structures”).

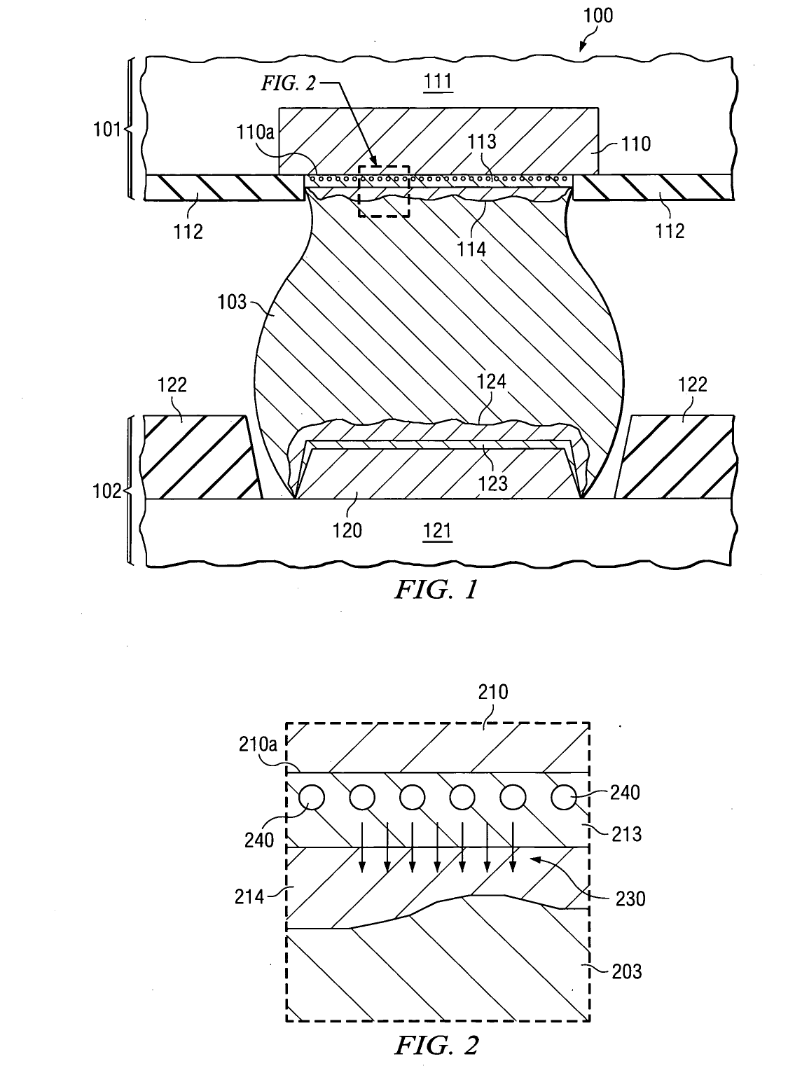

In the schematic cross section of FIG. 1, a portion of a product, generally designated 100, is shown comprising a device part designated 101, a substrate designated 102, and a means for attachment, designated 103, which attaches device 101 to substrate 102.

In the specific embodiments discussed here, device 101 is a semiconductor device. It may be a semiconductor chip, or it may be a semiconductor package. In either case, the device has a metallic bond pad 110, which is made of copper. In some embodiments, bond pad 110 comprises a copper alloy. Bond pad 110 is surrounded by insulating material 111; examples are silicon dioxide, silicon nitride, silicon carbide, low-k dielectrics, polymer compounds such as polyimides, glass ceramics, FR-4 and other composites. Part of the pad surface 110a is covered by insulating material 112, which is often referred to as solder mask, since it operates to contain the shape of a solder connection. Examples for insulating materials 112 are polyimides and other polymer compounds of low dielectric constant.

In the specific embodiments discussed here, substrate 102 is a board as used in electronic products. It may be referred to as printed circuit board, or motherboard. Substrate 102 has a metallic contact pad 120, which is made of copper. In some embodiments, contact pad 120 comprises a copper alloy. Contact pad 120 is surrounded by insulating material 121 and solder mask 122. Examples for insulating material 121 are composite materials such as FR-4, FR-5, glass fiber re-enforced polymers, and alumina. Examples for solder mask 122 are polyimides and other polymer compounds of low dielectric constant.

Preferred attachment materials for attachment body 103 include solders made of tin and tin alloys. Because of the low melting temperatures they offer, eutectic tin compounds are particularly preferred. Examples are tin/silver (eutectic temperature 221° C.), tin/bismuth (139° C.), tin/indium (120° C.), tin/zinc (189.5 IC), and tin/lead (183° C.). Compared to these alloys, the melting point of pure tin is at 231.9° C. For reasons of manufacturability and joint strength, the most preferred solder compounds are tin/lead and tin/silver.

The portion 100 of the product in FIG. 1 is depicted after the assembly process, in which attachment material 103 has undergone the reflow process to form solder joints with the bond pad 110 and the contact pad 120. As an effect of the temperature of the reflow process and the time needed for assembly, copper atoms from the bond pad 110 and the contact pad 120 have been diffusing into the solder material 103. This diffusion process is continuing at the elevated temperatures (especially at temperatures in excess of 100° C.) of temperature cycle testing, device storage, and device operation.

At the stage, when the solder connection between device 101 and substrate 102 is formed by solder 103, as depicted in FIG. 1, the copper diffusion from bond pad 110 and contact pad 120 has formed a copper rich intermetallic at the copper-to-solder interfaces. The dominant component of this compound is copper-3-tin (Cu₃Sn). In FIG. 1, the Cu₃Sn regions are designated 113 at the device side of the assembly, and 123 at the substrate side of the assembly. Further into the solder, an intermetallic compound of less copper content is formed, copper-6-tin-5 (Cu₆Sn₅). In FIG. 1, these Cu₆Sn₅ regions are designated 114 at the device side of the assembly, and 124 at the substrate side of the assembly.

In FIG. 1, a region “A” is marked at the device bond pad/solder joint, which is enlarged in FIG. 2, generally designated “A”; an analogous magnified view can be taken from a region at the substrate contact pad/solder joint. In FIG. 2, the copper 210 of the device bond pad has a surface 210a. Following the concentration gradient, copper atoms 230 are diffusing away from surface 210a into solder 203, which is one of the tin alloys listed above. Preferred are the alloys tin/silver (SnAg) and tin/lead (SnPb). The diffusing copper atoms have formed the intermetallic compounds 213, consisting of Cu₃Sn, and 214, consisting of Cu₆Sn₅.

In FIG. 2 are schematically further shown a plurality of Kirkendall voids 240. The observation by the applicants of Kirkendall voids at the interface form the basis for the invention. As FIG. 2 shows, the applicants found that the majority of these voids are arrayed along the Cu₃Sn-side of the copper surface 210a in more or less uniform distribution. The applicants understood that the Kirkendall voids are originally formed as copper deficiencies along the joint, because the copper diffusion into the tin solder is much larger than the tin back-diffusion into the copper. The voids end up on the Cu₃Sn side of the joint, however, because the boundary of the joint moves during the time of the high temperature processes.

The applicants discovered that a high density of Kirkendall voids represents a significant mechanical weakening of the joint; a dense row of voids is at risk of developing into a crack. It has been shown experimentally that devices with Kirkendall voids along the copper/solder joint (developed after aging, or numerous temperature cycles, or insufficiently cooled device operation, etc.) have a high failure rate in bulk solder pull tests and board-level drop tests; see, for instance, Tz-Cheng Chiu, K. Zeng, R. Stierman, D. Edwards and K. Ano, “Effect of Thermal Aging on Board Level Drop Reliability for Pb-Free BGA Packages”, El. Comp. Tech. Conf., pp. 1256-1262 (2004).

The copper diffusion is driven by the material density difference; the amount of transported copper is directly proportional to the gradient of copper concentration, times the diffusion coefficient. Experiments performed by the applicants as the basis of the present invention have shown that the formation of Kirkendall voids can be significantly reduced by kinetically retarding the copper diffusion rate through the interface. According to the invention, applicants are able to retard copper diffusion by adding copper into, for instance, a tin-based solder. The amount of copper to be added depends on the selection of the solder alloy.

One embodiment of the present invention is a metal interconnect structure, which has a bond pad of copper or copper alloy belonging to a semiconductor chip, a semiconductor package, or generally to a device. A body of eutectic tin/lead alloy is in contact with the bond pad. This alloy includes copper in an amount greater than 0.08 weight percent and less than 2.0 weight percent. The structure finally has a contact pad comprising copper, or copper alloy, in contact with the alloy body; this contact pad belongs to a substrate, board, or other external part. The body of solder alloy is often formed as a ball or bump, and may take a drum-like shape with an enlarged center portion (as indicated in FIG. 1) after the reflow process. The solder alloy forms intermetallic joints both with the bond pad and the contact pad. Experiments by the applicants have confirmed that the addition of copper in the weight percent range indicated reduces the formation of Kirkendall voids to low or non-existent values, and it remains low even after prolonged temperature excursions.

Another embodiment of the present invention is a metal interconnect structure, which has a bond pad of copper as part of a device such as a semiconductor chip or a semiconductor package. In contact with this bond pad is a body of eutectic tin/silver alloy, wherein this alloy includes copper in an amount greater than 0.9 weight percent and less than 2.0 weight percent. The structure finally has a contact pad, as part of a substrate or some other external part, in contact with the alloy body, wherein this contact pad is made of copper or a copper alloy.

Another embodiment of the present invention is a metal interconnect structure comprising a bond pad of a first metal and a body of reflow alloy in contact with the bond pad. The alloy includes a quantity of the first metal sufficient to retard the diffusion of the first metal into the alloy, and to substantially prevent the formation of Kirkendall voids at the first metal/alloy body intermetallic joint, and concurrently to keep the alloy melting temperature less than about 20° C. above the eutectic temperature of the alloy. Finally, the structure has a contact pad comprising a third metal in contact with the alloy body.

Examples of first metal and of the third metal are copper; a copper alloy such as copper with about 0.1 to about 5 weight percent admixture of zinc, bismuth, tin, silver, gold or other alloy metals, which provide to the copper a specifically desired characteristic such as mechanical hardness or electrical conductivity; brass; and bronze.

Examples of reflow alloys are:
Eutectic tin/lead solder having a quantity of copper greater than 0.08 weight percent and less than 2.0 weight percent.
Eutectic tin/silver solder having a quantity of copper greater than 0.9 weight percent and less than 2.0 weight percent.
Eutectic tin/bismuth solder having a quantity of copper greater than 0.02 weight percent and less than 2.0 weight percent.

Eutectic tin/zinc solder having a quantity of copper greater than 0.003 weight percent and less than 2.0 weight percent.

A ternary tin/silver/copper solder having a copper content so that the total copper content after the addition of diffused-in copper is greater than 0.9 weight percent and less than 2.0 weight percent.

For some embodiments, especially outside the semiconductor technology, an alloy melting temperature higher than about 20° C. above the eutectic temperature of the alloy may be acceptable. In those embodiments, the copper content of the solder alloy may be raised higher than the limits quoted in order to prevent the formation of Kirkendall voids even further.

While this invention has been described in reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

1. A metal interconnect structure comprising:
a bond pad comprising copper;
a body of eutectic tin/lead alloy in contact with said bond pad, at least a portion of said alloy including copper in an amount greater than 0.08 weight percent and less than 2.0 weight percent; and a contact pad comprising copper in contact with said alloy body.

2. The interconnect structure according to claim 1 wherein said alloy forms intermetallic joints with said bond pad and said contact pad.

3. A metal interconnect structure comprising:
a bond pad comprising copper;
a body of eutectic tin/silver alloy in contact with said bond pad, at least a portion of said alloy including copper in an amount greater than 0.9 weight percent and less than 2.0 weight percent; and
a contact pad comprising copper in contact with said alloy body.

4. A metal interconnect structure comprising:
a bond pad comprising a first metal;
a body of reflow alloy in contact with said bond pad, said alloy including a quantity of said first metal sufficient to retard the diffusion of said first metal into said alloy, and to substantially prevent the formation of Kirkendall voids at the first metal/alloy body intermetallic joint, and concurrently to keep the alloy melting temperature less than about 20° C. above the eutectic temperature of said alloy without inclusion of the first metal; and
a contact pad comprising a third metal in contact with said alloy body.

5. The interconnect structure according to claim 4 wherein said first metal is copper or a copper alloy.

6. The interconnect structure according to claim 4 wherein said reflow alloy is a eutectic tin/lead solder.

7. The interconnect structure according to claim 6 wherein said quantity of said first metal is greater than 0.08 and less than 2.0 weight percent.

8. The interconnect structure according to claim 4 wherein said reflow alloy is a eutectic tin/silver solder.

9. The interconnect structure according to claim 8 wherein said quantity of said first metal is greater than 0.9 and less than 2.0 weight percent.

10. The interconnect structure according to claim 4 wherein said reflow alloy is a eutectic tin/bismuth solder.

11. The interconnect structure according to claim 10 wherein said quantity of said first metal is greater than 0.02 and less than 2.0 weight percent.

12. The interconnect structure according to claim 4 wherein said reflow alloy is a eutectic tin/zinc solder.

13. The interconnect structure according to claim 12 wherein said quantity of said first metal is greater than 0.003 and less than 2.0 weight percent.

14. The interconnect structure according to claim 4 wherein said third metal is copper or a copper alloy.

15. The interconnect structure according to claim 4 wherein said reflow alloy is a tin/silver/copper solder having a copper content so that the total copper content after the addition of diffused-in copper is greater than 0.9 and less than 2.0 weight percent.
